(19) United States
(12) Patent Application Publication
(10) Pub. No.: US 2025/0249537 A1
(43) Pub. Date: Aug. 7, 2025

(54) LASER APPARATUS AND METHOD FOR FABRICATING THE SAME

(71) Applicant: Samsung Display Co., LTD., Yongin-si (KR)

(72) Inventors: Joong Bae PYOUN, Yongin-si (KR); Seok Hwan KIM, Yongin-si (KR); Min Kyu KIM, Yongin-si (KR); Hong Ju MUN, Yongin-si (KR)

(21) Appl. No.: 18/910,288

(22) Filed: Oct. 9, 2024

(30) Foreign Application Priority Data
Feb. 21, 2024 (KR) 10-2024-0024908

(51) Int. Cl. B23K 26/70; B23K 26/082; B23K 26/38

(52) U.S. Cl. CPC B23K 26/702; B23K 26/082; B23K 26/38

(57) ABSTRACT

A laser apparatus including: a stage supporting a substrate; a scanner which processes the substrate by irradiating a laser beam to the substrate based on a preset target processing line and forms a display panel; a scanner transfer unit which moves the scanner; and a control unit which controls a movement of the scanner transfer unit, where the control unit includes a display part which displays a user interface, and the user interface includes an input field which receives a correction value for correcting a coordinate of an actual processing line of the processed display panel.

This application claims priority to Korean Patent Application No. 10-2024-0024908, filed on Feb. 21, 2024, and all the benefits accruing therefrom under 35 U.S.C. § 119, the content of which in its entirety is herein incorporated by reference.

### BACKGROUND

### 1. Field

Embodiments of the disclosure relate to a laser apparatus, and more particularly, to a laser apparatus capable of reducing fabrication cost and a method for fabricating a display device using the same.

### 2. Description of the Related Art

The importance of display devices is steadily increasing with the development of multimedia technology. Along with this trend, various types of display devices such as liquid crystal display devices, organic light-emitting display devices and the like are being used.

In a fabrication process of a display device, a laser beam may be used to cut the display device to a desired dimension and shape.

### SUMMARY

Features of the disclosure provide a laser apparatus capable of reducing fabrication cost and a method for fabricating a display device using the same.

In an embodiment of the disclosure, a laser apparatus including: a stage supporting a substrate; a scanner which processes the substrate by irradiating a laser beam to the substrate based on a preset target processing line and forms a display panel; a scanner transfer unit which moves the scanner; and a control unit which controls a movement of the scanner transfer unit, where the control unit includes a display part which displays a user interface, and the user interface includes an input field which receives a correction value for correcting a coordinate of an actual processing line of the processed display panel.

In an embodiment, the input field may include: a first-first input field which receives a first X-correction value for correcting an X-axis coordinate of a first actual point of the actual processing line so that the X-axis coordinate of the first actual point and an X-axis coordinate of a first target point of the target processing line in a first quadrant are close to each other; and a first-second input field which receives a first Y-correction value for correcting a Y-axis coordinate of the first actual point of the actual processing line so that the Y-axis coordinate of the first actual point and a Y-axis coordinate of the first target point of the target processing line in the first quadrant are close to each other.

In an embodiment, the input field may further include: a second-first input field which receives a second X-correction value for correcting an X-axis coordinate of a second actual point of the actual processing line so that the X-axis coordinate of the second actual point and an X-axis coordinate of a second target point of the target processing line in a second quadrant are close to each other; and a second-second input field which receives a second Y-correction value for correcting a Y-axis coordinate of the second actual point of the actual processing line so that the Y-axis coordinate of the second actual point and a Y-axis coordinate of the second target point of the target processing line in the second quadrant are close to each other.

In an embodiment, the input field further may include: a third-first input field which receives a third X-correction value for correcting an X-axis coordinate of a third actual point of the actual processing line so that the X-axis coordinate of the third actual point and an X-axis coordinate of a third target point of the target processing line in a third quadrant are close to each other; and a third-second input field which receives a third Y-correction value for correcting a Y-axis coordinate of the third actual point of the actual processing line so that the Y-axis coordinate of the third actual point and a Y-axis coordinate of the third target point of the target processing line in the third quadrant are close to each other.

In an embodiment, the input field may further include: a fourth-first input field which receives a fourth X-correction value for correcting an X-axis coordinate of a fourth actual point of the actual processing line so that the X-axis coordinate of the fourth actual point and an X-axis coordinate of a fourth target point of the target processing line in a fourth quadrant are close to each other; and a fourth-second input field which receives a fourth Y-correction value for correcting a Y-axis coordinate of the fourth actual point of the actual processing line so that the Y-axis coordinate of the fourth actual point and a Y-axis coordinate of the fourth target point of the target processing line in the fourth quadrant are close to each other.

In an embodiment, the user interface may further include a name field corresponding to the input field.

In an embodiment of the disclosure, a method for fabricating a display device, including: processing a substrate by irradiating a laser beam to the substrate based on a preset target processing line to form a display panel; determining whether the processed display panel meets a preset specification; and when the processed display panel does not meet the preset specification, detecting an actual processing line corresponding to an edge of the processed display panel, and correcting the actual processing line based on the target processing line, where the correcting the actual processing line includes: detecting a coordinate of an actual point of the actual processing line; and moving the coordinate of the actual point to a coordinate of a target point of the target processing line corresponding to the actual point.

In an embodiment, the actual processing line may include a first actual point, a second actual point, a third actual point, and a fourth actual point respectively corresponding to a first edge, a second edge, a third edge, and a fourth edge of the processed display panel, and the target processing line may include a first target point disposed in a first quadrant, a second target point disposed in a second quadrant, a third target point disposed in a third quadrant, and a fourth target point disposed in a fourth quadrant of a preset coordinate system.

In an embodiment, the first actual point may be disposed in the first quadrant, the second actual point may be disposed in the second quadrant, the third actual point may be disposed in the third quadrant, and the fourth actual point may be disposed in the fourth quadrant.

In an embodiment, the detecting the coordinate of the actual point of the actual processing line may include: calculating respective coordinates of the first actual point, the second actual point, the third actual point, and the fourth actual point.

In an embodiment, the moving the coordinate of the actual point to the coordinate of the target point of the target processing line corresponding to the actual point may include: moving the coordinate of the first actual point to a coordinate of the first target point; moving the coordinate of the second actual point to a coordinate of the second target point; moving the coordinate of the third actual point to a coordinate of the third target point; and moving the coordinate of the fourth actual point to a coordinate of the fourth target point.

In an embodiment, the moving the coordinate of the first actual point to the coordinate of the first target point may include: adding a first X-correction value to an X-axis coordinate of the first actual point, and adding a first Y-correction value to a Y-axis coordinate of the first actual point.

In an embodiment, the moving the coordinate of the second actual point to the coordinate of the second target point may include: adding a second X-correction value to an X-axis coordinate of the second actual point, and adding a second Y-correction value to a Y-axis coordinate of the second actual point.

In an embodiment, the moving the coordinate of the third actual point to the coordinate of the third target point may include: adding a third X-correction value to an X-axis coordinate of the third actual point, and adding a third Y-correction value to a Y-axis coordinate of the third actual point.

In an embodiment, the moving the coordinate of the fourth actual point to the coordinate of the fourth target point may include: adding a fourth X-correction value to an X-axis coordinate of the fourth actual point, and adding a fourth Y-correction value to a Y-axis coordinate of the fourth actual point.

In an embodiment, the actual point may be disposed at an intersection point between a first actual side of the actual processing line and a second actual side of the actual processing line connected to the first actual side.

In an embodiment, the detecting the coordinate of the actual point of the actual processing line may include: calculating respective coordinates of a first point and a second point on an imaginary first straight line corresponding to the first actual side, based on an inspection key disposed at one edge of the display panel; calculating respective coordinates of a third point and a fourth point on an imaginary second straight line corresponding to the second actual side, based on an inspection key disposed at one edge of the display panel; calculating an equation of the imaginary first straight line, based on the coordinate of the first point and the coordinate of the second point; calculating an equation of the imaginary second straight line, based on the coordinate of the third point and the coordinate of the fourth point; and calculating a coordinate corresponding to an intersection point between the imaginary first straight line and the imaginary second straight line, based on the equation of the imaginary first straight line and the equation of the imaginary second straight line, where the coordinate of the intersection point corresponds to the coordinate of the actual point.

In an embodiment, the inspection key may include: a first inspection key; a second inspection key disposed adjacent to the first inspection key in a first direction; and a third inspection key disposed adjacent to the first inspection key in a second direction intersecting the first direction.

In an embodiment, the calculating the respective coordinates of the first point and the second point on the imaginary first straight line may include: calculating the coordinate of the first point based on a coordinate of the first inspection key and a distance between the first inspection key and the first point; and calculating the coordinate of the second point based on a coordinate of the second inspection key and a distance between the second inspection key and the second point.

In an embodiment, the calculating the respective coordinates of the third point and the fourth point on the imaginary second straight line may include: calculating the coordinate of the third point based on a coordinate of the first inspection key and a distance between the first inspection key and the third point; and calculating the coordinate of the fourth point based on a coordinate of the third inspection key and a distance between the third inspection key and the fourth point.

In an embodiment, the correcting the actual processing line further may include: correcting an entirety of the actual processing line in a shift manner.

In an embodiment, the detecting the coordinate of the actual point of the actual processing line and the moving the coordinate of the actual point to the coordinate of the target point of the target processing line corresponding to the actual point may be performed after the correcting the entirety of the actual processing line in the shift manner.

In an embodiment, the correcting the actual processing line may further include: correcting an entirety of the actual processing line in a rotational manner.

In an embodiment, the detecting the coordinate of the actual point of the actual processing line and the moving the coordinate of the actual point to the coordinate of the target point of the target processing line corresponding to the actual point may be performed after the correcting the entirety of the actual processing line in the rotational manner.

In an embodiment, the correcting the actual processing line may further include: correcting an entirety of the actual processing line in a scaling manner.

In an embodiment, the detecting the coordinate of the actual point of the actual processing line and the moving the coordinate of the actual point to the coordinate of the target point of the target processing line corresponding to the actual point may be performed after the correcting the entirety of the actual processing line in the scaling manner.

In the laser apparatus and the method for fabricating the display device using the same in an embodiment, the consumption rate of a substrate used in processing a display panel may be reduced. Accordingly, the fabrication cost of the display device may be reduced.

The effects in the embodiments of the disclosure are not limited to those mentioned above and more various effects are included in the following description of the disclosure.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view of an embodiment of a laser apparatus;

FIG. 2 is a schematic diagram of an embodiment of a scanner;

FIGS. 3 and 4 are diagrams illustrating an embodiment of the shape of a display panel when a laser beam from the laser apparatus is irradiated along a target processing line of a target substrate;

FIGS. 5 and 6 are diagrams illustrating an embodiment of the shape of the display panel when the laser beam from the laser apparatus has been irradiated inconsistently with the target processing line of the target substrate;

FIG. 7 is a diagram illustrating an embodiment of a method for fabricating a display device;

FIGS. 8 to 11 are diagrams illustrating a correction operation of the target processing line;

FIGS. 12 and 13 are diagrams illustrating an embodiment of the shape of the display panel when the laser beam from the laser apparatus is irradiated along the corrected processing line of the target substrate;

FIG. 14 is a diagram illustrating an embodiment of a method of correcting an actual processing line;

FIG. 15 is a diagram illustrating an embodiment of a method of correcting the actual processing line;

FIG. 16 is a diagram illustrating an embodiment of a method of correcting the actual processing line according to one embodiment;

FIG. 17 is a diagram illustrating an embodiment of a user interface of a laser apparatus; and

FIG. 18 is a diagram illustrating the effect of an embodiment of a method for fabricating a display device.

### DETAILED DESCRIPTION

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The drawing figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments may be practiced individually or in combination.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

The term such as “unit” as used herein is intended to mean a hardware component that performs a predetermined function. The hardware component may include a circuitry such as a field-programmable gate array (“FPGA”) or an application-specific integrated circuit (“ASIC”), for example.

Hereinafter, embodiments of the disclosure will be described with reference to the accompanying drawings.

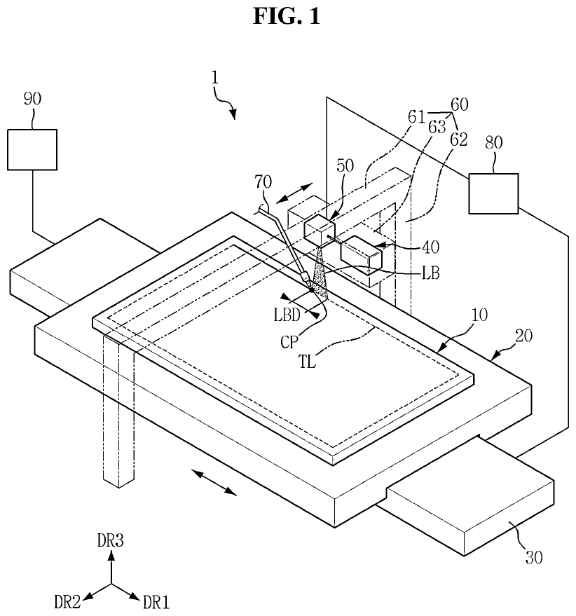

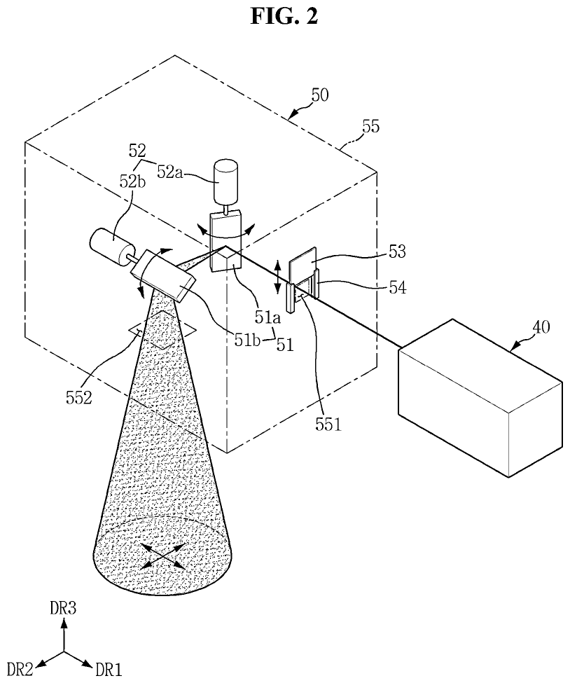

FIG. 1 is a perspective view of an embodiment of an intense-light apparatus (e.g., a laser apparatus 1), and FIG. 2 is a schematic diagram of an embodiment of a scanner 50. In an embodiment, FIG. 2 may be a schematic diagram of the scanner 50 of FIG. 1, for example.

Referring to FIGS. 1 and 2, the laser apparatus 1 in an embodiment may draw an intense light (e.g., a laser beam LB) along an imaginary target processing line TL formed on a target substrate (also referred to as a substrate) 10 to separate and cut one side and an opposite side with respect to the target processing line TL.

The laser apparatus 1 may include a stage 20 on which the target substrate 10 (e.g., a base display panel cut into cell units) is seated, a stage transfer unit 30 for moving the stage 20, an intense-light providing unit (e.g., a laser providing unit 40) for generating the laser beam LB, the scanner 50 for changing the path of the laser beam LB, a scanner transfer unit 60 for moving the scanner 50, a cooling unit 70 for cooling the target substrate 10, a control unit 80 for controlling the driving of the laser apparatus 1, and a stage encoder 90 for providing position information of the stage 20 to the control unit 80.

The stage 20 may support the target substrate 10. The stage transfer unit 30 may move the stage 20. In an embodiment, the stage transfer unit 30 may move the stage 20 in the first direction DR1, for example. However, the disclosure is not limited thereto, and the stage transfer unit 30 may move the stage 20 in various directions. The stage transfer unit 30 may move the stage 20 to move the laser beam LB along the target processing line TL. However, without being limited thereto, the stage transfer unit 30 may move, instead of the stage 20, the laser providing unit 40 and the scanner 50 to be described later to move the laser beam LB along the target processing line TL, or may move the laser providing unit 40 and the scanner 50 at the same time to move the laser beam LB along the target processing line TL.

The laser providing unit 40 may generate and emit the laser beam LB. The laser beam LB generated by the laser providing unit 40 may be one of CO₂ laser, green laser, infrared laser, and ultraviolet laser, for example, but is not limited thereto.

The scanner 50 may be disposed on an optical path of the laser beam LB emitted from the laser providing unit 40. The laser beam LB emitted from the laser providing unit 40 may enter the scanner 50. The scanner 50 may adjust the optical path of the laser beam LB emitted from the laser providing unit 40. The laser beam LB whose optical path is adjusted by the scanner 50 may be irradiated along the target processing line TL of the target substrate 10. Specifically, the scanner 50 may swing the laser beam LB. Therefore, an incidence angle of the laser beam LB on a top surface of the target substrate 10 may be changed within a predetermined range. A predetermined range in which the laser beam LB is incident on the top surface of the target substrate 10 may be a light irradiation section LBD. The light irradiation section LBD may be formed along the target processing line TL.

The scanner 50 may include a mirror unit 51 for reflecting the laser beam LB emitted from the laser providing unit 40, a mirror driving unit 52 for driving the mirror unit 51, a shutter 53 for blocking the laser beam LB, and a shutter driving unit 54 for driving the shutter 53.

The mirror unit 51 may swing the laser beam LB emitted from the laser providing unit 40 to move a target aiming point of the laser beam LB forward and backward. The mirror unit 51 may include a first mirror unit 51a for swinging the laser beam LB in the first direction DR1 and a second mirror unit 51b for swinging the laser beam LB in the second direction DR2. The laser beam LB may be irradiated in a plan view defined by the first direction DR1 and the second direction DR2 through the first mirror unit 51a and the second mirror unit 51b.

The mirror driving unit 52 may drive the mirror unit 51 and selectively adjust the movement of the mirror unit 51. The mirror driving unit 52 may include a first mirror driving unit 52a for driving the first mirror unit 51a and a second mirror driving unit 52b for driving the second mirror unit 51b.

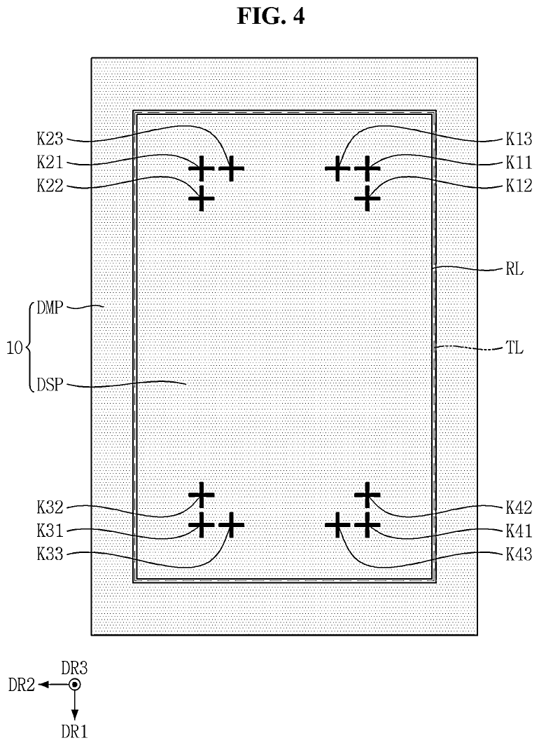

The shutter 53 may block the laser beam LB emitted from the laser providing unit 40. The shutter 53 may be disposed on the optical path of the laser beam LB. The shutter 53 may control the laser beam LB entering the scanner 50 through an opening/closing operation. In an embodiment, when the shutter 53 is opened, the laser beam LB may enter the scanner 50, and when the shutter 53 is closed, the laser beam LB may not enter the scanner 50, for example. The shutter 53 may be opened/closed in a sliding manner, for example. However, the disclosure is not limited thereto, and the shutter 53 may be opened/closed in various manners. Although FIG. 4 illustrates that the shutter 53 is disposed on one surface of a housing 55 of the scanner 50 to be described later, the disclosure is not limited thereto and the shutter 53 may be disposed inside or outside the housing 55.

The opening/closing operation of the shutter 53 may be controlled by the control unit 80. Specifically, whether to open or close the shutter 53 may be determined based on a position of a target aiming point of the laser beam LB in the target substrate 10.

The shutter 53 may be driven by the shutter driving unit 54. As described above, the shutter 53 may be opened/closed in a sliding manner, and the shutter driving unit 54 may drive the sliding of the shutter 53. The shutter driving unit 54 may be controlled by the control unit 80. Specifically, the shutter driving unit 54 may receive a control signal for the shutter 53 from the control unit 80 and open/close the shutter 53. The opening/closing operation of the shutter 53 by the control unit 80 will be described later.

The scanner 50 may further include the housing 55 for accommodating the mirror unit 51 and the mirror driving unit 52. The housing 55 may form an outer shape of the scanner 50 and may provide a space for accommodating the mirror unit 51 and the mirror driving unit 52. The housing 55 may include a light inlet port 551 that is opened on the laser providing unit 40 side to allow the laser beam LB emitted from the laser providing unit 40 to enter the housing 55, and a light irradiation port 552 that is opened to irradiate the laser beam LB toward the target substrate 10 through the mirror unit 51.

The laser providing unit 40 and the scanner 50 may be moved in the second direction DR2 by the scanner transfer unit 60. The scanner transfer unit 60 may have a gantry structure. The scanner transfer unit 60 may include a horizontal supporting part 61 extending in a horizontal direction, a vertical supporting part 62 connected to the horizontal supporting part 61 and extending in a third direction DR3, and a horizontal moving part 63 which is installed on the horizontal supporting part 61 and moves the laser providing unit 40 and the scanner 50 in the second direction DR2. The horizontal supporting part 61 may have a shape extended in the second direction DR2. The vertical supporting part 62 may be disposed on one side and an opposite side of the stage 20 in the second direction DR2. The laser providing unit 40 and the scanner 50 may be disposed inside the horizontal moving part 63. The scanner transfer unit 60 may be connected to the control unit 80, and the movement of the scanner transfer unit 60 may be controlled by the control unit 80.

The cooling unit 70 may cool the target substrate 10 to which the laser beam LB is irradiated. Specifically, the cooling unit 70 may cool a rear part of the light irradiation section LBD with respect to the moving direction of the light irradiation section LBD. When the laser beam LB is irradiated on the target substrate 10, the light irradiation section LBD to which the laser beam LB is irradiated may be instantaneously heated. At this time, compressive stress due to heat may occur at the light irradiation section LBD of the target substrate 10. The cooling unit 70 may instantaneously cool a rear edge of the light irradiation section LBD with respect to the moving direction of the light irradiation section LBD. At this time, tensile stress may occur at the cooled portion. When thermal shock (compressive stress and tensile stress) due to such a rapid temperature change is applied to the target substrate 10, fine cracks are generated. Accordingly, the target substrate 10 may be cut along the target processing line TL. The degree of cooling of the target substrate 10 by the cooling unit 70 may be adjusted depending on a material of the target substrate 10 and types of the laser beam LB.

The control unit 80 may control the overall operation of the laser apparatus 1. Specifically, the control unit 80 may control the stage transfer unit 30, the laser providing unit 40, the scanner 50, the scanner transfer unit 60, and the cooling unit 70. The control unit 80 may control the cutting process of the target substrate 10 using information such as the shape of the target processing line TL, the thickness and the material of the target substrate 10, the position of the stage 20, or the like.

Further, the control unit 80 may control the opening/closing operation of the shutter 53 by controlling the shutter driving unit 54. Specifically, the control unit 80 may control the shutter 53 to be closed when the target aiming point of the laser beam LB is disposed in a non-processing area. Further, when the target aiming point of the laser beam LB is disposed in a processing area, the shutter 53 may be controlled to be opened when the moving speed of the target aiming point of the laser beam LB is higher than or equal to a reference speed and may be controlled to be closed when the moving speed thereof is lower than the reference speed. The reference speed is set to uniformly irradiate the laser beam LB to each section of the target processing line TL, and may be lower than or equal to a moving speed of the laser beam LB irradiated on the target substrate 10.

The stage encoder 90 may provide position information of the stage 20 to the control unit 80. Specifically, the stage encoder 90 may detect the position of the stage 20, convert the detected position into an electric signal, and provide the electric signal to the control unit 80.

In the process of cutting the target substrate 10 using the laser beam LB, the laser beam LB is swung by the mirror unit 51. At the same time, the scanner 50 may be moved by the scanner transfer unit 60, and the stage 20 may be moved by the stage transfer unit 30. The above-described operations allow the laser beam LB to repeat forward movement in the moving direction of the light irradiation section LBD and backward movement in a direction opposite to the moving direction of the light irradiation section LBD. The forward moving distance of the laser beam LB may be greater than the backward moving distance thereof. Therefore, the light irradiation section LBD may be moved while repeating the forward movement and the backward movement of the laser beam LB. In an embodiment, during the cutting process, when the light irradiation section LBD is moved toward one side of the first direction DR1, the movement of the laser beam LB toward one side of the first direction DR1 may be the forward movement, and the movement of the laser beam LB toward an opposite side of the first direction DR1 may be the backward movement, for example.

The laser beam LB may provide energy to the target processing line TL of the target substrate 10 while moving forward and backward along the target processing line TL. Specifically, the spot where the laser beam LB is instantaneously irradiated may be moved forward and backward along the target processing line TL to provide energy to the target processing line TL of the target substrate 10. The irradiation spots per unit area in the target processing line TL may be uniform overall, but the disclosure is not limited thereto. The target substrate 10 may be cut along the target processing line TL by the energy provided by the laser beam LB.

Hereinafter, a method for fabricating a display device using the above-described laser apparatus 1 will be described. The method for fabricating the display device to be described below is a method of forming a display panel (e.g., a display panel of the display device) by cutting the target substrate 10 (e.g., the base display panel cut into cell units) using the laser beam LB.

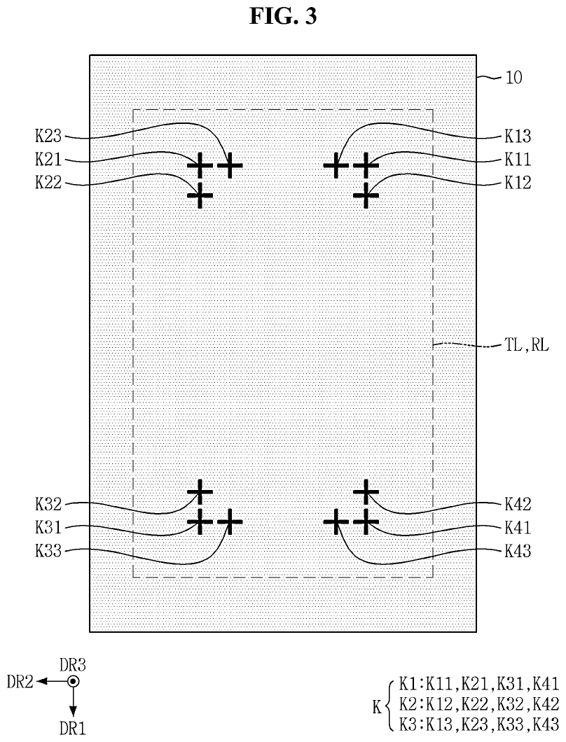

FIGS. 3 and 4 are diagrams illustrating an embodiment of the shape of a display panel DSP when the laser beam LB from the laser apparatus 1 is irradiated along the target processing line TL of the target substrate 10.

As shown in FIG. 3, the laser beam LB (refer to FIG. 1) emitted from the scanner 50 (refer to FIGS. 1 and 2) of the laser apparatus 1 (refer to FIG. 1) may be irradiated along the target processing line TL of the target substrate 10. Then, as shown in FIG. 4, the target substrate 10 may be cut along the target processing line TL to be separated into the display panel DSP and a dummy panel DMP.

When the laser beam LB (refer to FIG. 1) is normally irradiated along the target processing line TL as shown in FIG. 3, the display panel DSP may be processed into a desired shape. In an embodiment, since the target processing line TL and an actual processing line RL along which the laser beam LB is actually irradiated substantially coincide, the edge of the display panel DSP shown in FIG. 4 may substantially coincide with the target processing line TL, for example. Therefore, the display panel DSP of FIG. 4 may have a normal shape that satisfies a preset specification. Accordingly, the display panel DSP of FIG. 4 may be fabricated as a normal product.

Whether or not the processed display panel DSP is defective (e.g., whether it is defective in processing) may be determined by a vision inspection device. In an embodiment, the processed display panel DSP may be transferred to the vision inspection device while being disposed on the stage 20 (refer to FIG. 1) and then captured, for example. The processed display panel DSP may include three inspection keys K disposed at each corner. In an embodiment, as shown in FIG. 4, three inspection keys K11, K12, and K13 may be disposed at a first corner of the display panel DSP, three inspection keys K21, K22, and K23 may be disposed at a second corner of the display panel DSP, three inspection keys K31, K32, and K33 may be disposed at a third corner of the display panel DSP, and three inspection keys K41, K42, and K43 may be disposed at a fourth corner of the display panel DSP, for example. At each corner, a first inspection key K1 (e.g., K11, K21, K31, K41) and a second inspection key K2 (e.g., K12, K22, K32, K42) may be disposed adjacent to each other in the first direction DR1 respectively, and at each corner, the first inspection key K1 (e.g., K11, K21, K31, K41) and a third inspection key K3 (e.g., K13, K23, K33, K43) may be disposed adjacent to each other in the second direction DR2 respectively.

The vision inspection device may compare the distance between the inspection keys K of the processed display panel DSP and the actual processing line RL, and determine whether the display panel DSP has been normally processed based on the comparison result. In an embodiment, the vision inspection device may capture an image of the processed display panel DSP of FIG. 4, and in the captured image of the display panel DSP, calculate a horizontal distance (e.g., a distance in the second direction DR2) and a vertical distance (e.g., a distance in the first direction DR1) between the first inspection key K1 at each corner of the display panel DSP and the actual processing line RL, and determine whether each calculated horizontal distance is within a preset critical horizontal distance range and whether each calculated vertical distance is within a preset critical vertical distance range, for example. Here, the critical horizontal distance range may be defined as a range obtained by adding a lower limit of a preset horizontal tolerance and an upper limit of the horizontal tolerance to a horizontal distance between the first inspection key K1 and the target processing line TL, and the critical vertical distance range may be defined as a range obtained by adding a lower limit of a preset vertical tolerance and an upper limit of the vertical tolerance to a vertical distance between the first inspection key K1 and the target processing line TL. The vision inspection device may determine that the display panel DSP has been processed normally when each of the calculated horizontal distances is within the critical horizontal distance range and each of the calculated vertical distances is within the critical vertical distance range. The vision inspection device may determine that the display panel DSP has been processed abnormally when at least one of the calculated horizontal distances is outside the critical horizontal distance range or at least one of the calculated vertical distances is outside the critical vertical distance range.

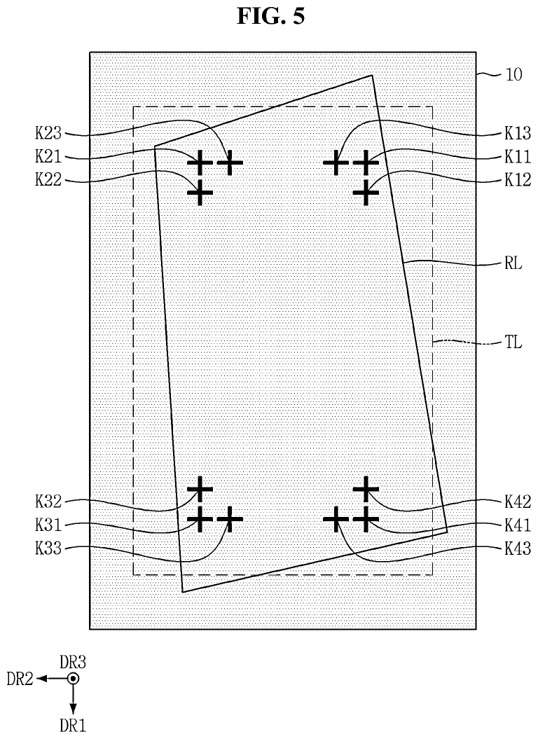

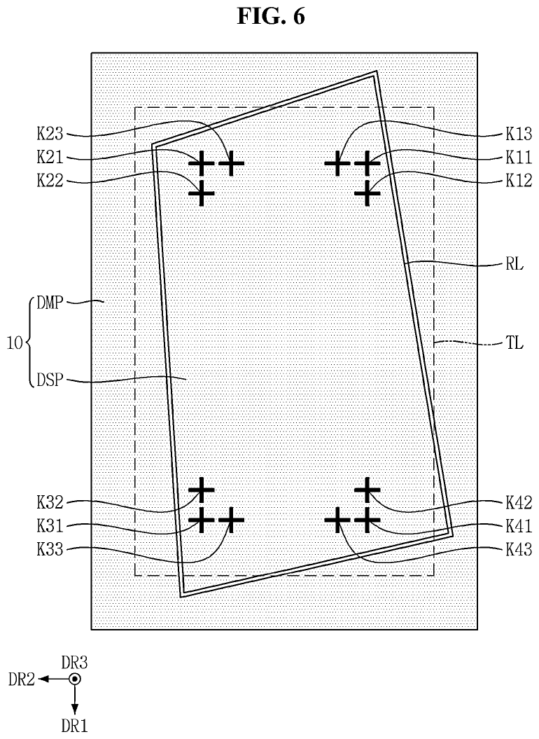

When the target substrate 10 is placed on the stage 20, the laser beam LB from the scanner 50 may be irradiated onto the target substrate 10 inconsistently with the aforementioned target processing line TL due to various causes such as distortion of the target substrate 10, elongation of the target substrate 10, and transfer error of the scanner 50. Such an example will be described below with reference to FIGS. 5 and 6.

FIGS. 5 and 6 are diagrams illustrating an embodiment of the shape of the display panel DSP when the laser beam LB from the laser apparatus 1 has been irradiated inconsistently with the target processing line TL of the target substrate 10.

As shown in FIG. 5, the target processing line TL and the actual processing line RL may not coincide. Therefore, as shown in FIG. 5, an area defined by the actual processing line RL and an area defined by the target processing line TL may have different shapes.

As shown in FIG. 5, the laser beam LB emitted from the scanner 50 of the laser apparatus 1 may be irradiated along the actual processing line RL of the target substrate 10. Then, as shown in FIG. 6, the target substrate 10 may be cut along the actual processing line RL to be separated into the display panel DSP and the dummy panel DMP.

As shown in FIG. 5, when the laser beam LB is irradiated inconsistently with the target processing line TL, the display panel DSP may be processed into an undesired shape. In an embodiment, since the target processing line TL and the actual processing line RL along which the laser beam LB is actually irradiated do not coincide, the edge of the display panel DSP shown in FIG. 6 does not coincide with the target processing line TL, for example. Therefore, the display panel DSP of FIG. 6 may have an abnormal shape that does not satisfy the preset specification. Accordingly, the display panel DSP of FIG. 6 is not utilized as a product and is discarded. In an embodiment, the display panel DSP of FIG. 6 may be determined to be a defective display panel DSP when, as a result of inspection by the vision inspection device, it is determined that the distance between at least one of the inspection keys K of the display panel DSP of FIG. 6 and the actual processing line RL is outside the critical horizontal distance range or the critical vertical distance range described above, for example.

In order to process the display panel DSP in a normal shape, the irradiation path of the laser beam LB needs to be corrected such that a distance difference (e.g., offset) between the target processing line TL and the actual processing line RL described above is within a preset tolerance range. To this end, in an embodiment, the movement path of the scanner 50 may be corrected, so that the aforementioned offset may be within the tolerance range. Until the aforementioned offset falls within the tolerance range, a relatively large number of target substrates 10 may be processed and then discarded. A processing method of the display panel DSP in an embodiment, for minimizing the number of target substrates 10 discarded in this way, will be described in detail as follows.

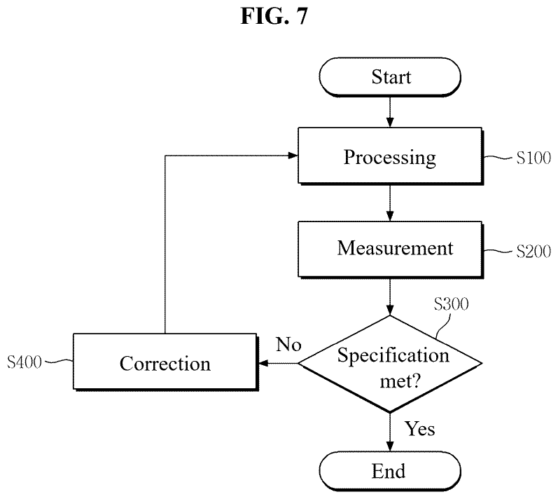

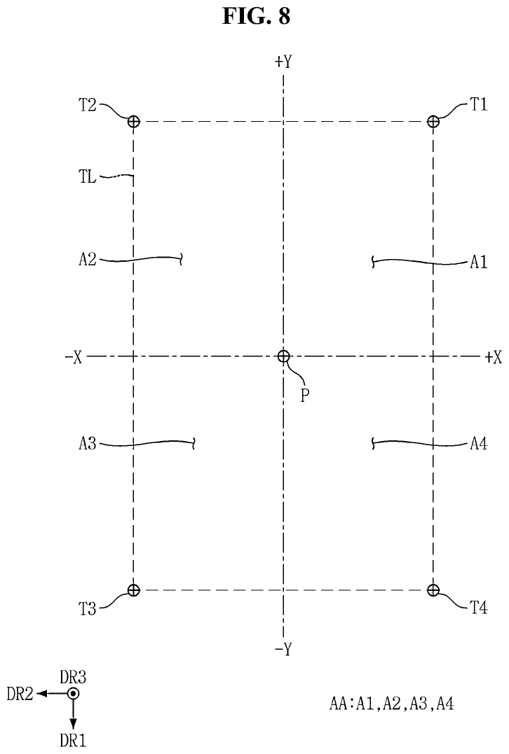

FIG. 7 is a diagram illustrating an embodiment of a method for fabricating a display device. FIGS. 8 to 11 are diagrams illustrating a correction operation of the target processing line TL.

First, according to FIG. 7, the target substrate 10 may be processed based on the preset target processing line TL (operation S100). In other words, by cutting the target substrate 10 along the target processing line TL, the display panel DSP may be processed.

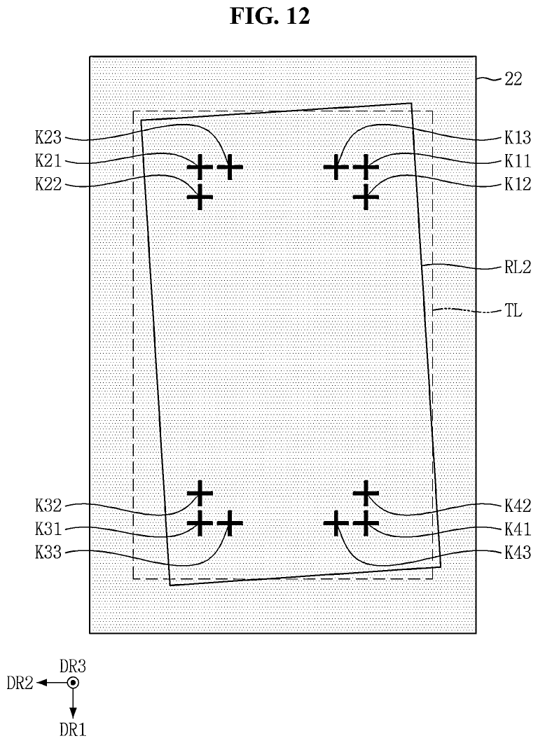

Thereafter, a determination may be performed as to whether the processed display panel DSP has been processed to meet the preset specification (operation S300). For this purpose, the distance between the inspection key and the actual processing line RL may be measured by the vision inspection device as described above (operation S200). As a result of the determination in operation S300, when the processed display panel DSP meets the preset specification (hereinafter also referred to as a specification), the same processing operation may be performed on a subsequent target substrate 22 (refer to FIG. 12) without correction of the target processing line TL described above. In other words, the subsequent target substrate 22 may also be cut along the target processing line TL described above.

As a result of the above-described determination in operation S300, when the processed display panel DSP does not meet the specification, the correction operation for the target processing line TL described above may be performed (operation S400). The correction operation for the target processing line TL will be described in detail as follows.

First, as shown in FIG. 8, the target processing line TL may define a normal shape of the display panel DSP to be processed into a desired shape. An area (hereinafter, also referred to as a target processing area AA) defined by the target processing line TL may include four points T1, T2, T3, and T4. In an embodiment, the target processing area AA may include a first target point T1, a second target point T2, a third target point T3, and a fourth target point T4, for example.

The target processing area AA may include four quadrants A1, A2, A3, and A4 divided by an X-axis and a Y-axis. In an embodiment, the target processing area AA may include a first quadrant A1, a second quadrant A2, a third quadrant A3, and a fourth quadrant A4, for example. The first quadrant A1 of the target processing area AA may be a quadrant defined by a positive X-axis and a positive Y-axis, and the second quadrant A2 of the target processing area AA may be a quadrant defined by a negative X-axis and the positive Y-axis, the third quadrant A3 of the target processing area AA may be a quadrant defined by the negative X-axis and a negative Y-axis, and the fourth quadrant A4 of the target processing area AA may be a quadrant defined by the positive X-axis and the negative Y-axis. The above-described target processing area AA may include two or three quadrants, or may include five or more quadrants.

The first target point T1 may be set as two-dimensional coordinates disposed in the first quadrant A1 of the target processing area AA, the second target point T2 may be set as two-dimensional coordinates disposed in the second quadrant A2 of the target processing area AA, the third target point T3 may be set as two-dimensional coordinates disposed in the third quadrant A3 of the target processing area AA, and the fourth target point T4 may be set as two-dimensional coordinates disposed in the fourth quadrant A4 of the target processing area AA.

The coordinates of each of the target points T1 to T4 may be set with respect to an intersection point (hereinafter, also referred to as a zero point P) between the X-axis and the Y-axis. In an embodiment, the coordinates of the first target point T1 may be two-dimensional coordinates including a value of one point on the positive X-axis from the zero point P and a value of one point on the positive Y-axis from the zero point P, the coordinates of the second target point T2 may be two-dimensional coordinates including a value of one point on the negative X-axis from the zero point P and a value of one point on the positive Y-axis from the zero point P, the coordinates of the third target point T3 may be two-dimensional coordinates including a value of one point on the negative X-axis from the zero point P and a value of one point on the negative Y-axis from the zero point P, and the coordinates of the fourth target point T4 may be two-dimensional coordinates including a value of one point on the positive X-axis from the zero point P and a value of one point on the negative Y-axis from the zero point P, for example.

The target processing area AA may be preset based on the shape of the display panel DSP to be processed. In other words, the coordinates of each of the first target point T1, the second target point T2, the third target point T3, and the fourth target point T4 in the target processing area AA may be preset based on the shape of the display panel DSP to be processed.

The two-dimensional coordinates of each of the first to fourth target points T1 to T4 in the target processing area AA may be pre-stored in a storage part (e.g., memory) of the control unit 80, for example. In other words, the two-dimensional coordinates of the first target point T1, the two-dimensional coordinates of the second target point T2, the two-dimensional coordinates of the third target point T3, and the two-dimensional coordinates of the fourth target point T4 may be pre-stored in the memory of the control unit 80.

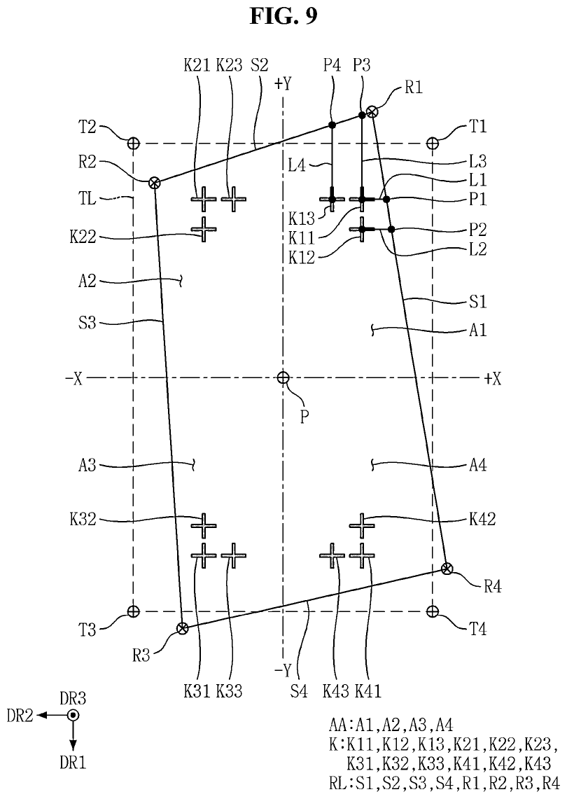

As shown in FIG. 9, the actual processing line RL may correspond to the edge of the display panel DSP that has actually been irradiated by the laser beam LB and processed. In an embodiment, the actual processing line RL may have a first actual side S1, a second actual side S2, a third actual side S3, and a fourth actual side S4, for example. The first actual side S1 may correspond to a first edge of the processed display panel DSP, the second actual side S2 may correspond to a second edge of the processed display panel DSP, the third actual side S3 may correspond to a third edge of the processed display panel DSP, and the fourth actual side S4 may correspond to a fourth edge of the processed display panel DSP. An area (hereinafter, also referred to as an actual processing area) surrounded by the first to fourth actual sides S1 to S4 of the actual processing line RL may have the shape of the processed display panel DSP.

The actual processing line RL may have four points R1, R2, R3, and R4. In an embodiment, the actual processing area may include a first actual point R1, a second actual point R2, a third actual point R3, and a fourth actual point R4, for example. The first actual point R1 may be a point at which the first actual side S1 and the second actual side S2 are connected to each other, the second actual point R2 may be a point at which the second actual side S2 and the third actual side S3 are connected to each other, the third actual point R3 may be a point at which the third actual side S3 and the fourth actual side S4 are connected to each other, and the fourth actual point R4 may be a point at which the fourth actual side S4 and the first actual side S1 are connected to each other.

The coordinates of the first actual point R1, the coordinates of the second actual point R2, the coordinates of the third actual point R3, and the coordinates of the fourth actual point R4 may each be two-dimensional coordinates, and the coordinates of each of the first to fourth actual points R1 to R4 may be obtained from the vision inspection device. In an embodiment, the vision inspection device may capture an image of the processed display panel DSP, analyze the captured image to detect four corners of the display panel DSP, and calculate two-dimensional coordinates for each of the four detected corners, for example. The coordinates of the first actual point R1, the second actual point R2, the third actual point R3, and the fourth actual point R4 may be calculated based on the above zero point P. In this way, the coordinates of each of the first to fourth actual points R1 to R4 in the actual processing area may be detected by the vision inspection device after the display panel DSP is processed.

The coordinates of each of the actual points R1 to R4 may be calculated based on the actual sides S1 to S4. In an embodiment, the coordinates of the first actual point R1 may be coordinates of an intersection point between an imaginary first straight line corresponding to the first actual side S1 and an imaginary second straight line corresponding to the second actual side S2, the coordinates of the second actual point R2 may be coordinates of an intersection point between the above second straight line and an imaginary third straight line corresponding to the third actual side S3, the coordinates of the third actual point R3 may be coordinates of an intersection point between the above imaginary third straight line (hereinafter also referred to as a third straight line) and an imaginary fourth straight line corresponding to the fourth actual side S4, and the coordinates of the fourth actual point R4 may be coordinates of an intersection point between the above imaginary fourth straight line (hereinafter also referred to as a fourth straight line) and the above first straight line, for example.

In each quadrant, three inspection keys (e.g., first inspection keys K11, K21, K31, and K41, second inspection keys K12, K22, K32, and K42, and third inspection keys K13, K23, K33, and K43) may be disposed. The first inspection key (e.g., K11) and the second inspection key (e.g., K12) may be disposed adjacent to each other in the Y-axis direction (or the first direction DR1), and the first inspection key (e.g., K11) and the third inspection key (e.g., K13) may be disposed adjacent to each other in the X-axis direction (or the second direction DR2). The respective coordinates of the three inspection keys K in each of the quadrants A1 to A4 are preset coordinates. In an embodiment, the respective coordinates of the first to third inspection keys K11, K12, and K13 in the first quadrant A1, the respective coordinates of the first to third inspection keys K21, K22, and K23 in the second quadrant A2, the respective coordinates of the first to third inspection keys K31, K32, and K33 in the third quadrant A3, and the respective coordinates of the first to third inspection keys K41, K42, and K43 in the fourth quadrant A4 may be obtained from the vision inspection device described above, for example.

The imaginary first straight line (hereinafter also referred to as a first straight line) corresponding to the first actual side S1 may be calculated by an equation of a straight line passing through two points (e.g., a first point P1 and a second point P2) on the first actual side S1. This will be described in detail as follows.

The coordinates of the first point P1 on the first actual side S1 may be calculated based on the coordinates of the first inspection key K11. In an embodiment, the X-axis coordinate of the first point P1 on the first actual side S1 may be the same as the X-axis coordinate of a point moved by a first distance L1 in the X-axis direction from the first inspection key K11, and the Y-axis coordinate of the first point P1 on the first actual side S1 may be the same as the Y-axis coordinate of the first inspection key K11, for example. Here, the first distance L1 may be parallel to the X-axis direction. The X-axis coordinate of the first point P1 may be calculated based on the already known X-axis coordinate of the first inspection key K11 and the distance between the first inspection key K11 and the first point P1. The first distance L1 may be calculated and obtained from the vision inspection device, for example. In an embodiment, the vision inspection device may detect the first distance L1 in the X-axis direction between the first inspection key K11 and the first point P1 through the already known X-axis coordinate of the first inspection key K11.

The coordinates of the second point P2 on the first actual side S1 may be calculated based on the coordinates of the second inspection key K12. In an embodiment, the X-axis coordinate of the second point P2 on the first actual side S1 may be the same as the X-axis coordinate of a point moved by a second distance L2 in the X-axis direction from the second inspection key K12, and the Y-axis coordinate of the second point P2 on the first actual side S1 may be the same as the Y-axis coordinate of the second inspection key K12, for example. Here, the second distance L2 may be parallel to the X-axis direction. The X-axis coordinate of the second point P2 may be calculated based on the already known X-axis coordinate of the second inspection key K12 and the distance between the second inspection key K12 and the second point P2. The second distance L2 may be calculated and obtained from the vision inspection device, for example. In an embodiment, the vision inspection device may detect the second distance L2 in the X-axis direction between the second inspection key K12 and the second point P2 through the already known X-axis coordinate of the second inspection key K12.

As described above, when the coordinates of the first point P1 and the coordinates of the second point P2 are calculated, an equation of the first straight line passing through the first point P1 and the second point P2 may be calculated. In an embodiment, the equation of the first straight line corresponding to the first actual side S1 may be calculated based on the coordinates of the first point P1 and the coordinates of the second point P2, for example.

The coordinates of a third point P3 on the second actual side S2 may be calculated based on the coordinates of the first inspection key K11. In an embodiment, the X-axis coordinate of the third point P3 on the second actual side S2 may be the same as the X-axis coordinate of the first inspection key K11, and the Y-axis coordinate of the third point P3 on the second actual side S2 may be the same as the Y-axis coordinate of a point moved by a third distance L3 in the Y-axis direction from the first inspection key K11, for example. Here, the third distance L3 may be parallel to the Y-axis direction. The Y-axis coordinate of the third point P3 may be calculated based on the already known Y-axis coordinate of the first inspection key K11 and the distance between the first inspection key K11 and the third point P3. The third distance L3 may be calculated and obtained from the vision inspection device, for example. In an embodiment, the vision inspection device may detect the third distance L3 in the Y-axis direction between the first inspection key K11 and the third point P3 through the already known Y-axis coordinate of the first inspection key K11.

The coordinates of a fourth point P4 on the second actual side S2 may be calculated based on the coordinates of the third inspection key K13. In an embodiment, the X-axis coordinate of the fourth point P4 on the second actual side S2 may be the same as the X-axis coordinate of the third inspection key K13, and the Y-axis coordinate of the fourth point P4 on the second actual side S2 may be the same as the Y-axis coordinate of a point moved by a fourth distance L4 in the Y-axis direction from the third inspection key K13, for example. Here, the fourth distance L4 may be parallel to the Y-axis direction. The Y-axis coordinate of the fourth point P4 may be calculated by the distance between the already known Y-axis coordinate of the third inspection key K13 and the distance between the third inspection key K13 and the fourth point P4. The fourth distance L4 may be calculated and obtained from the vision inspection device, for example. In an embodiment, the vision inspection device may detect the fourth distance L4 in the Y-axis direction between the third inspection key K13 and the fourth point P4 through the already known Y-axis coordinate of the third inspection key K13.

As described above, when the coordinates of the third point P3 and the coordinates of the fourth point P4 are calculated, an equation of the imaginary second straight line (hereinafter also referred to as a second straight line) passing through the third point P3 and the fourth point P4 may be calculated. In an embodiment, the equation of the second straight line corresponding to the second actual side S2 may be calculated based on the coordinates of the third point P3 and the coordinates of the fourth point P4, for example.

The coordinates of the first actual point R1 may be calculated by the equation of the first straight line and the equation of the second straight line described above. In an embodiment, the X-axis coordinate and the Y-axis coordinate of the first actual point R1 may be the X-axis coordinate and the Y-axis coordinate of the intersection point between the first straight line and the second straight line, respectively, for example.

In this way, the coordinates of the second actual point R2 in the second quadrant A2, the coordinates of the third actual point R3 in the third quadrant A3, and the coordinates of the fourth actual point R4 in the fourth quadrant A4 may each be calculated. In other words, the coordinates of each of the four actual points R1, R2, R3, and R4 on the actual processing line RL may be calculated.

Subsequently, the horizontal distance (e.g., the first distance L1) between the first inspection key K11 of the first quadrant A1 and the first actual side S1, the vertical distance (e.g., the third distance L3) between the first inspection key K11 of the first quadrant A1 and the second actual side S2, the horizontal distance between the first inspection key K21 of the second quadrant A2 and the third actual side S3, the vertical distance between the first inspection key K21 of the second quadrant A2 and the second actual side S2, the horizontal distance between the first inspection key K31 of the third quadrant A3 and the third actual side S3, the vertical distance between the first inspection key K31 of the third quadrant A3 and the fourth actual side S4, the horizontal distance between the first inspection key K41 of the fourth quadrant A4 and the first actual side S1, and the vertical distance between the first inspection key K41 of the fourth quadrant A4 and the fourth actual side S4 may be compared to a critical distance (e.g., a critical horizontal distance and a critical vertical distance), and based on the comparison result, it may be determined whether the display panel DSP is defective or not.

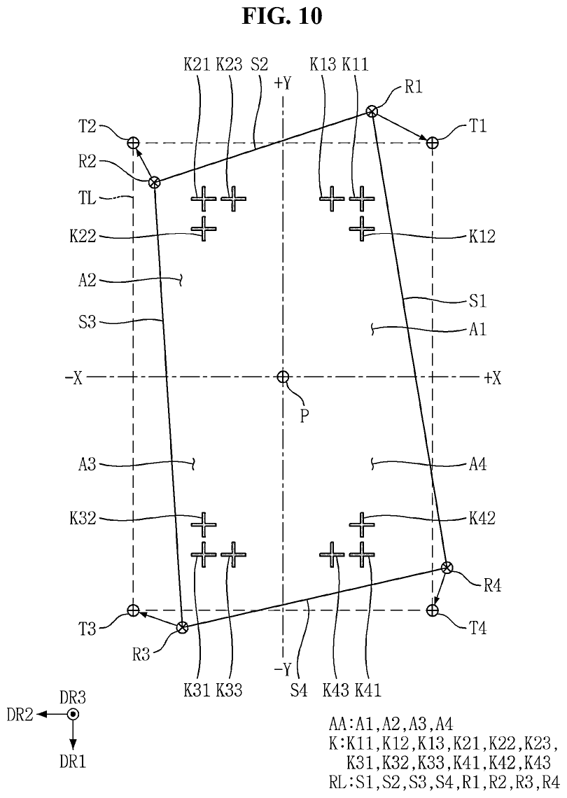

As a result of the comparison, when the processed display panel DSP does not meet the preset specification, an operation for correcting the actual processing line RL may be performed as described above. In an embodiment, as in the example shown in FIG. 10, a correction operation (e.g., an actual processing line correction operation) may be performed to move the first actual point R1, the second actual point R2, the third actual point R3, and the fourth actual point R4 described above to the first target point T1, the second target point T2, the third target point T3, and the fourth target point T4, respectively, for example. To this end, in an embodiment, the X-axis coordinate of the first actual point R1 may be increased by a first X-correction value to match the X-axis coordinate of the first target point T1, and the Y-axis coordinate of the first actual point R1 may be decreased by a first Y-correction value to match the Y-axis coordinate of the first target point T1. In addition, the X-axis coordinate of the second actual point R2 may be decreased by a second X-correction value to match the X-axis coordinate of the second target point T2, and the Y-axis coordinate of the second actual point R2 may be increased by a second Y-correction value to match the Y-axis coordinate of the second target point T2. In addition, the X-axis coordinate of the third actual point R3 may be decreased by a third X-correction value to match the X-axis coordinate of the third target point T3, and the Y-axis coordinate of the third actual point R3 may be increased by a third Y-correction value to match the Y-axis coordinate of the third target point T3. In addition, the X-axis coordinate of the fourth actual point R4 may be decreased by a fourth X-correction value to match the X-axis coordinate of the fourth target point T4, and the Y-axis coordinate of the fourth actual point R4 may be decreased by a fourth Y-correction value to match the Y-axis coordinate of the fourth target point T4. Here, the first X-correction value, the first Y-correction value, the second X-correction value, the second Y-correction value, the third X-correction value, the third Y-correction value, the fourth X-correction value, and the fourth Y-correction value may be individually adjusted. Accordingly, the first X-correction value of the first quadrant A1, the second X-correction value of the second quadrant A2, the third X-correction value of the third quadrant A3, and the fourth X-correction value of the fourth quadrant A4 may have different values from each other, and the first Y-correction value of the first quadrant A1, the second Y-correction value of the second quadrant A2, the third Y-correction value of the third quadrant A3, and the fourth Y-correction value of the fourth quadrant A4 may have different values from each other.

In an embodiment, the first X-correction value, the first Y-correction value, the second X-correction value, the second Y-correction value, the third X-correction value, the third Y-correction value, the fourth X-correction value, and the fourth Y-correction value may be directly inputted by an operator. In an embodiment, the operator may correct the actual processing line RL by inputting the first X-correction value, the first Y-correction value, the second X-correction value, the second Y-correction value, the third X-correction value, the third Y-correction value, the fourth X-correction value, and the fourth Y-correction value described above into input fields displayed on a display part (e.g., screen or panel) of the control unit 80, for example.

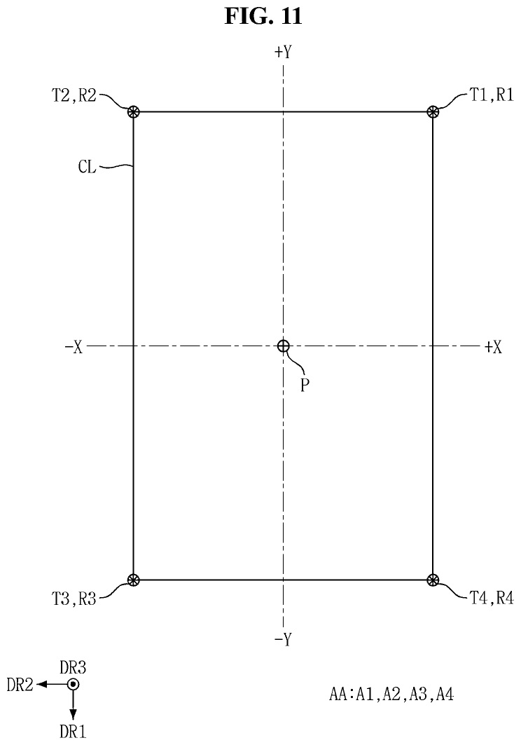

Then, as shown in FIG. 11, the corrected first actual point R1 may have a value identical or similar to the first target point T1, the corrected second actual point R2 may have a value identical or similar to the second target point T2, the corrected third actual point R3 may have a value identical or similar to the third target point T3, and the corrected fourth actual point R4 may have a value identical or similar to the fourth target point T4.

Thereafter, a corrected processing line CL including the corrected first actual point R1, the corrected second actual point R2, the corrected third actual point R3, and the corrected fourth actual point R4 may be generated. In other words, the actual processing line RL may be converted into the corrected processing line CL by the above-described correction operation.

The control unit 80 may reset the transfer path of the scanner 50 based on the corrected processing line CL. In an embodiment, the control unit 80 may control the movement of the scanner 50 such that the scanner 50 moves along the corrected processing line CL described above, for example.

Thereafter, a new target substrate 10 may be disposed on the stage 20, and the processing operation may be performed on the new target substrate 10. In this case, when the scanner 50 is moved along the corrected processing line CL and the laser beam LB is irradiated normally along the corrected processing line CL, the display panel DSP may be processed into a desired shape. In an embodiment, the corrected processing line CL may substantially coincide with the actual processing line RL along which the laser beam LB is actually irradiated. In an embodiment, as in the example shown in FIG. 11, the new target substrate 10 may be cut normally along the corrected processing line CL that coincides with the target processing line TL, for example.

In an embodiment, since the correction values of the actual points R1 to R4 may be corrected individually, each actual point may have a value that is significantly close to the corresponding one of the target points T1 to T4 with only one correction operation, for example. Therefore, in an embodiment, the display panel DSP conforming to the specification may be fabricated using a smaller number of target substrates.

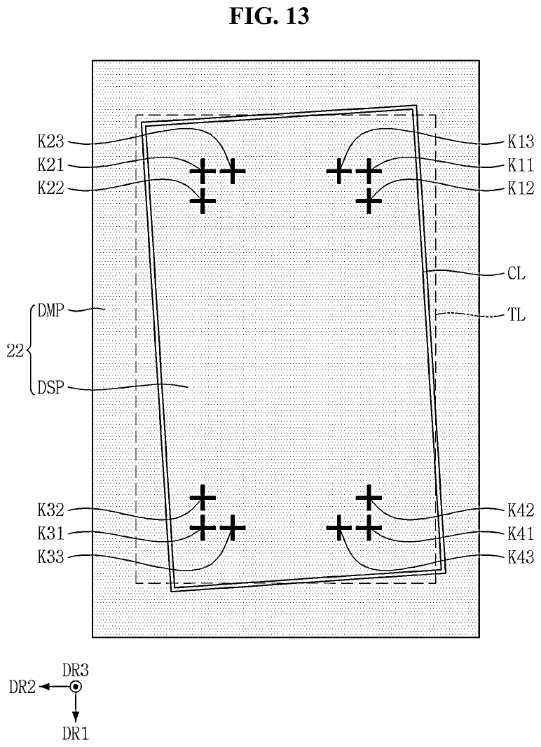

As described above, when the target substrate 10 is placed on the stage 20, the laser beam LB from the scanner 50 may be irradiated onto the target substrate 10 inconsistently with the above-described corrected processing line CL due to various causes such as distortion of the target substrate 10, elongation of the target substrate 10, and transfer error of the scanner 50. Such an example will be described below with reference to FIGS. 12 and 13.

FIGS. 12 and 13 are diagrams illustrating an embodiment of the shape of the display panel DSP when the laser beam LB from the laser apparatus 1 is irradiated along the corrected processing line CL of the target substrate (hereinafter also referred to as a substrate) 22. In an embodiment, FIGS. 12 and 13 are diagrams illustrating an operation of processing the target substrate 22 along the corrected processing line CL of FIG. 11, for example. The target substrate 22 of FIG. 12 is a target substrate different from the target substrate 10 of FIG. 5 described above.

As shown in FIG. 12, the target processing line TL and an actual processing line RL2 (hereinafter, also referred to as a second actual processing line RL2) corresponding to the corrected processing line CL may not coincide. Therefore, as shown in FIG. 12, an area defined by the second actual processing line RL2 and an area defined by the target processing line TL may have different shapes.

As shown in FIG. 12, the laser beam LB emitted from the scanner 50 of the laser apparatus 1 may be irradiated along the second actual processing line RL2 of the target substrate 22. Then, as shown in FIG. 13, the target substrate 22 may be cut along the second actual processing line RL2 to be separated into the display panel DSP and the dummy panel DMP.

When the display panel DSP processed along the second actual processing line RL2 meets the specification as a result of the inspection by the vision inspection device, the display panel DSP may be classified as a normal display panel DSP.

However, when the display panel DSP processed along the second actual processing line RL2 does not meet the specification as a result of inspection by the vision inspection device, an additional correction operation (hereinafter, also referred to as a second correction operation) for correcting the second actual processing line RL2 may be performed. The second correction operation may be performed in the above-described sequence as shown in FIGS. 8 to 11. In an embodiment, after the coordinates for each of the first actual point of the second actual processing line RL2 in the first quadrant A1, the second actual point of the second actual processing line RL2 in the second quadrant A2, the third actual point of the second actual processing line RL2 in the third quadrant A3, and the fourth actual point of the second actual processing line RL2 in the fourth quadrant A4 are calculated, a correction operation may be performed to move the first actual point, the second actual point, the third actual point, and the fourth actual point of the second actual processing line RL2 to the first target point T1, the second target point T2, the third target point T3, and the fourth target point T4 of the target processing line TL described above, respectively, for example.

The above-described correction operation of FIGS. 8 to 11 may be repeatedly performed on the new target substrate 10 until the processed display panel DSP meets the specification.

In an embodiment, during the correction operation of the actual processing line RL, the actual point in any one of the first to fourth quadrants A1 to A4 described above may be moved to the target point of the corresponding quadrant. In an embodiment, during the correction operation of the actual processing line RL, the actual point in at least one of the first to fourth quadrants A1 to A4 may be moved to the target point of the corresponding quadrant, for example.

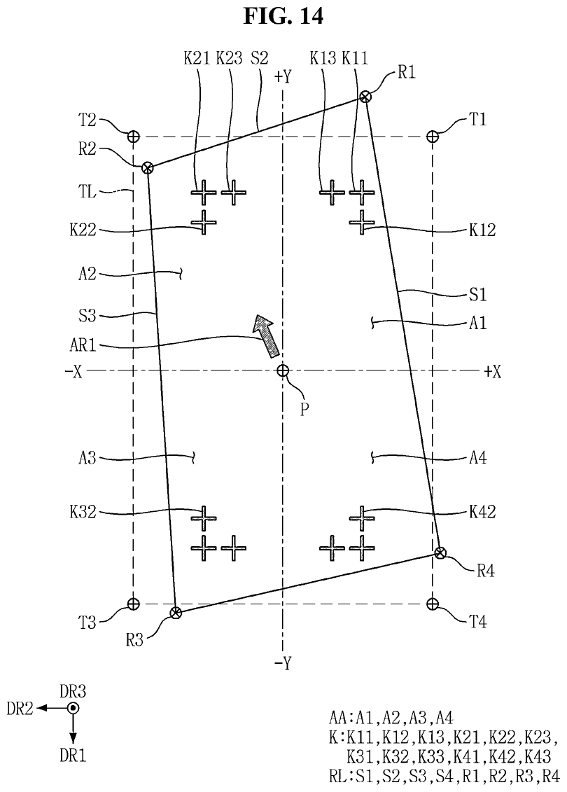

FIG. 14 is a diagram illustrating an embodiment of a method of correcting the actual processing line RL.

The actual processing line RL may be corrected in a shift manner. In an embodiment, as shown in FIG. 14, the actual processing line RL may be shifted along the direction of a first arrow AR1 with respect to the zero point P, for example. In other words, the entirety of the actual processing line RL may be shifted along the direction of the first arrow AR1. In this case, the first actual point R1, the second actual point R2, the third actual point R3, and the fourth actual point R4 may be moved by the same distance in the X-axis direction and the Y-axis direction.

In an embodiment, after the actual processing line RL is corrected in a shift manner, the first actual point R1, the second actual point R2, the third actual point R3, and the fourth actual point R4 may be moved to the first target point T1, the second target point T2, the third target point T3, and the fourth target point T4 by the additional correction operation of FIGS. 8 to 11 described above.

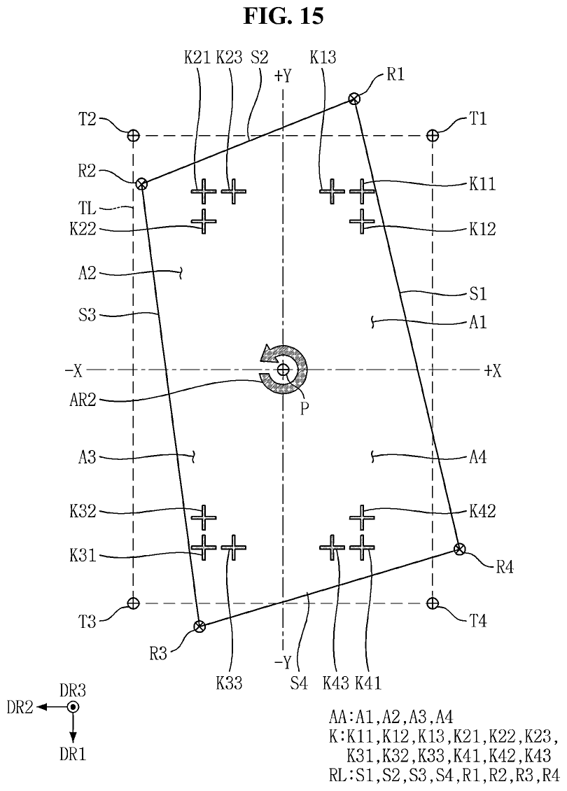

FIG. 15 is a diagram illustrating a method of correcting the actual processing line RL.

The actual processing line RL may be corrected in a rotational manner. In an embodiment, as shown in FIG. 15, the actual processing line RL may be rotated along the direction of a second arrow AR2 with respect to the zero point P, for example. In other words, the entirety of the actual processing line RL may be rotated along the direction of the second arrow AR2. In this case, the first actual point R1, the second actual point R2, the third actual point R3, and the fourth actual point R4 may be moved by the same angle around the zero point P.

In an embodiment, after the actual processing line RL is corrected in a rotational manner, the first actual point R1, the second actual point R2, the third actual point R3, and the fourth actual point R4 may be moved to the first target point T1, the second target point T2, the third target point T3, and the fourth target point T4, respectively, by the additional correction operation of FIGS. 8 to 11 described above.

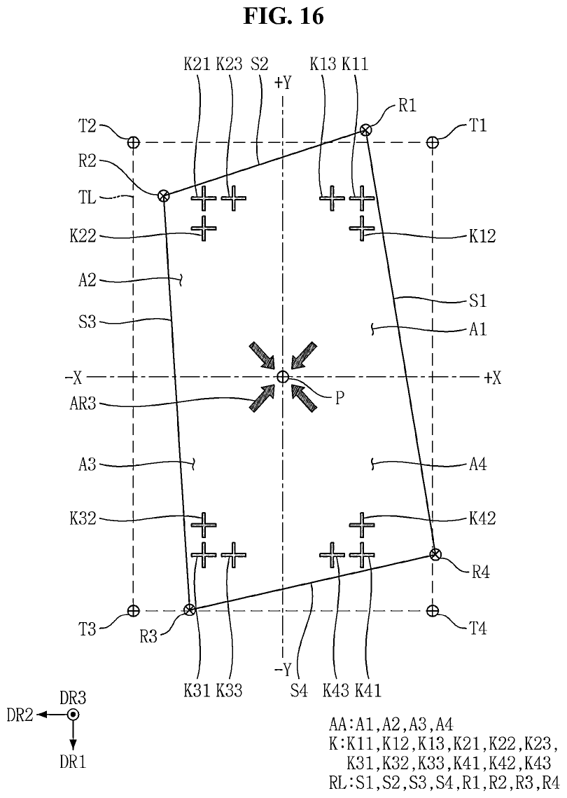

FIG. 16 is a diagram illustrating an embodiment of a method of correcting the actual processing line RL.

The actual processing line RL may be corrected in a scaling manner. In an embodiment, as shown in FIG. 16, the actual processing line RL may be scaled down at a predetermined ratio along the direction of a third arrow AR3 with respect to the zero point P, for example. In other words, the entirety of the actual processing line RL may be scaled down at a predetermined ratio along the direction of the third arrow AR3.

In an embodiment, after the actual processing line RL is corrected in a scaling-down manner, the first actual point R1, the second actual point R2, the third actual point R3, and the fourth actual point R4 may be moved to the first target point T1, the second target point T2, the third target point T3, and the fourth target point T4, respectively, by the additional correction operation of FIGS. 8 to 11 described above.

In an embodiment, the actual processing line RL may be corrected to be scaled up in a direction opposite to the third arrow AR3. In an embodiment, after the entirety of the actual processing line RL is corrected in a scaling-up manner at a predetermined ratio, the first actual point R1, the second actual point R2, the third actual point R3, and the fourth actual point R4 may be moved to the first target point T1, the second target point T2, the third target point T3, and the fourth target point T4, respectively, by the additional correction operation of FIGS. 8 to 11 described above, for example.

In an embodiment, the first to fourth target points T1 to T4, the first to fourth actual points R1 to R4, and the inspection keys K shown in FIGS. 8 to 11 may be displayed in the form of coordinate values on the display part of the control unit 80 described above. Based on the respective coordinate values of the first to fourth target points T1 to T4, the first to fourth actual points R1 to R4, and the inspection keys K on the display part of the control unit 80, the operator may confirm the shape of the target processing line TL, the shape of the actual processing line RL, and the position of the inspection keys K.

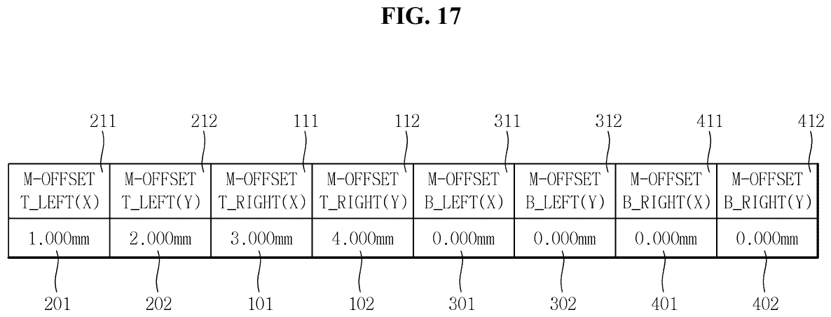

FIG. 17 is a diagram illustrating an embodiment of a user interface of a laser apparatus.

As shown in FIG. 17, the user interface of the laser apparatus 1 may include a plurality of name fields 111, 112, 211, 212, 311, 312, 411, and 412, and input fields 101, 102, 201, 202, 301, 302, 401, and 402.

The name fields 111, 112, 211, 212, 311, 312, 411, and 412, and the input fields 101, 102, 201, 202, 301, 302, 401, and 402 may be disposed to respectively correspond to each other.

The name for a position of each quadrant A1, A2, A3, A4 may be displayed in each of the name fields 111, 112, 211, 212, 311, 312, 411, and 412. In an embodiment, “M-OFFSET T_RIGHT(X)” displayed in a first-first name field 111 may mean a correction value (e.g., the first X-correction value) of the X-axis coordinate of the first quadrant A1, “M-OFFSET T_RIGHT(Y)” displayed in a first-second name field 112 may mean a correction value (e.g., the first Y-correction value) of the Y-axis coordinate of the first quadrant A1, “M-OFFSET T_LEFT(X)” displayed in a second-first name field 211 may mean a correction value (e.g., the second X-correction value) of the X-axis coordinate of the second quadrant A2, “M-OFFSET T_LEFT(Y)” displayed in a second-second name field 212 may mean a correction value (e.g., the second Y-correction value) of the Y-axis coordinate of the second quadrant A2, “M-OFFSET B_LEFT(X)” displayed in a third-first name field 311 may mean a correction value (e.g., the third X-correction value) of the X-axis coordinate of the third quadrant A3, and “M-OFFSET B_LEFT(Y)” displayed in a third-second name field 312 may mean a correction value (e.g., the third Y-correction value) of the Y-axis coordinate of the third quadrant A3, “M-OFFSET B_RIGHT(X)” displayed in a fourth-first name field 411 may mean a correction value (e.g., the fourth X-correction value) of the X-axis coordinate of the fourth quadrant A4, and “M-OFFSET B_RIGHT(Y)” displayed in a fourth-second name field 412 may mean a correction value (e.g., the fourth Y-correction value) of the Y-axis coordinate of the fourth quadrant A4, for example.

The correction value may be inputted to each of the input fields 101, 102, 201, 202, 301, 302, 401, and 402. In an embodiment, the first X-correction value may be inputted to a first-first input field 101, the first Y-correction value may be inputted to a first-second input field 102, the second X-correction value may be inputted to a second-first input field 201, the second Y-correction value may be inputted to a second-second input field 202, the third X-correction value may be inputted to a third-first input field 301, the third Y-correction value may be inputted to a third-second input field 302, the fourth X-correction value may be inputted to a fourth-first input field 401, and the fourth Y-correction value may be inputted to a fourth-second input field 402, for example. The aforementioned correction value may be inputted to the corresponding input field by a user.

The user interface of FIG. 17 may be displayed on the display part of the control unit described above, for example.

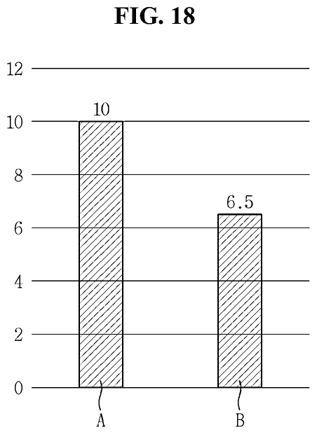

FIG. 18 is a diagram illustrating the effect of an embodiment of a method for fabricating a display device.

A first bar graph “A” in FIG. 18 shows the consumption rate of the target substrate according to a comparative invention, and a second bar graph “B” in FIG. 18 shows the consumption rate of the target substrate according to the method for fabricating the display device.

As shown in FIG. 18, in accordance with the method for fabricating the display device according to the comparative invention, the fabricated display panel could have dimensions that meet the specification after the processing operation has been performed on an average of about 10 target substrates. In contrast, in accordance with the method for fabricating the display device in an embodiment, the fabricated display panel could have dimensions that meet the specification after the processing operation has been performed on an average of about 6.5 target substrates. Accordingly, the method for fabricating the display device in an embodiment may reduce the substrate consumption rate by about 30% or more compared to the comparative invention.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A laser apparatus comprising:
a stage supporting a substrate;
a scanner which processes the substrate by irradiating a laser beam to the substrate based on a preset target processing line and forms a display panel;
a scanner transfer unit which moves the scanner; and
a control unit which controls a movement of the scanner transfer unit, the control unit comprising:
a display part which displays a user interface, the user interface comprising:
an input field which receives a correction value for correcting a coordinate of an actual processing line of the processed display panel.

2. The laser apparatus of claim 1, wherein the input field comprises:
a first-first input field which receives a first X-correction value for correcting an X-axis coordinate of a first actual point of the actual processing line so that the X-axis coordinate of the first actual point and an X-axis coordinate of a first target point of the preset target processing line in a first quadrant are close to each other; and
a first-second input field which receives a first Y-correction value for correcting a Y-axis coordinate of the first actual point of the actual processing line so that the Y-axis coordinate of the first actual point and a Y-axis coordinate of the first target point of the preset target processing line in the first quadrant are close to each other.

3. The laser apparatus of claim 2, wherein the input field further comprises:
a second-first input field which receives a second X-correction value for correcting an X-axis coordinate of a second actual point of the actual processing line so that the X-axis coordinate of the second actual point and an X-axis coordinate of a second target point of the preset target processing line in a second quadrant are close to each other; and
a second-second input field which receives a second Y-correction value for correcting a Y-axis coordinate of the second actual point of the actual processing line such that the Y-axis coordinate of the second actual point and a Y-axis coordinate of the second target point of the preset target processing line in the second quadrant are close to each other.

4. The laser apparatus of claim 3, wherein the input field further comprises:
a third-first input field which receives a third X-correction value for correcting an X-axis coordinate of a third actual point of the actual processing line so that the X-axis coordinate of the third actual point and an X-axis coordinate of a third target point of the preset target processing line in a third quadrant are close to each other; and
a third-second input field which receives a third Y-correction value for correcting a Y-axis coordinate of the third actual point of the actual processing line so that the Y-axis coordinate of the third actual point and a Y-axis coordinate of the third target point of the preset target processing line in the third quadrant are close to each other.

5. The laser apparatus of claim 4, wherein the input field further comprises:
a fourth-first input field which receives a fourth X-correction value for correcting an X-axis coordinate of a fourth actual point of the actual processing line so that the X-axis coordinate of the fourth actual point and an X-axis coordinate of a fourth target point of the preset target processing line in a fourth quadrant are close to each other; and
a fourth-second input field which receives a fourth Y-correction value for correcting a Y-axis coordinate of the fourth actual point of the actual processing line so that the Y-axis coordinate of the fourth actual point and a Y-axis coordinate of the fourth target point of the preset target processing line in the fourth quadrant are close to each other.

6. The laser apparatus of claim 1, wherein the user interface further comprises a name field corresponding to the input field.

7. A method for fabricating a display device, the method comprising:
processing a substrate by irradiating a laser beam to the substrate based on a preset target processing line to form a display panel;
determining whether the processed display panel meets a preset specification; and
in response to a case in which the processed display panel does not meet the preset specification, detecting an actual processing line corresponding to an edge of the processed display panel, and correcting the actual processing line based on the preset target processing line,
wherein the correcting the actual processing line comprises:
detecting a coordinate of an actual point of the actual processing line; and
moving the coordinate of the actual point to a coordinate of a target point of the preset target processing line corresponding to the actual point.

8. The method of claim 7, wherein the actual processing line comprises a first actual point, a second actual point, a third actual point, and a fourth actual point respectively corresponding to a first edge, a second edge, a third edge, and a fourth edge of the processed display panel, and
the preset target processing line comprises a first target point disposed in a first quadrant, a second target point disposed in a second quadrant, a third target point disposed in a third quadrant, and a fourth target point disposed in a fourth quadrant of a preset coordinate system.

9. The method of claim 8, wherein the first actual point is disposed in the first quadrant,
the second actual point is disposed in the second quadrant,
the third actual point is disposed in the third quadrant, and
the fourth actual point is disposed in the fourth quadrant.

10. The method of claim 9, wherein the detecting the coordinate of the actual point of the actual processing line comprises:
calculating respective coordinates of the first actual point, the second actual point, the third actual point, and the fourth actual point.

11. The method of claim 10, wherein the moving the coordinate of the actual point to the coordinate of the target point of the preset target processing line corresponding to the actual point comprises:
moving the coordinate of the first actual point to a coordinate of the first target point;
moving the coordinate of the second actual point to a coordinate of the second target point;
moving the coordinate of the third actual point to a coordinate of the third target point; and
moving the coordinate of the fourth actual point to a coordinate of the fourth target point.

12. The method of claim 11, wherein the moving the coordinate of the first actual point to the coordinate of the first target point comprises:
adding a first X-correction value to an X-axis coordinate of the first actual point, and adding a first Y-correction value to a Y-axis coordinate of the first actual point.

13. The method of claim 11, wherein the moving the coordinate of the second actual point to the coordinate of the second target point comprises:
adding a second X-correction value to an X-axis coordinate of the second actual point, and adding a second Y-correction value to a Y-axis coordinate of the second actual point.

14. The method of claim 11, wherein the moving the coordinate of the third actual point to the coordinate of the third target point comprises:
adding a third X-correction value to an X-axis coordinate of the third actual point, and adding a third Y-correction value to a Y-axis coordinate of the third actual point.

15. The method of claim 11, wherein the moving the coordinate of the fourth actual point to the coordinate of the fourth target point comprises:
adding a fourth X-correction value to an X-axis coordinate of the fourth actual point, and adding a fourth Y-correction value to a Y-axis coordinate of the fourth actual point.

16. The method of claim 7, wherein the actual point is disposed at an intersection point between a first actual side of the actual processing line and a second actual side of the actual processing line connected to the first actual side.

17. The method of claim 16, wherein the detecting the coordinate of the actual point of the actual processing line comprises:
calculating respective coordinates of a first point and a second point on an imaginary first straight line corresponding to the first actual side, based on an inspection key disposed at one edge of the display panel;
calculating respective coordinates of a third point and a fourth point on an imaginary second straight line corresponding to the second actual side, based on an inspection key disposed at one edge of the display panel;
calculating an equation of the imaginary first straight line, based on the coordinate of the first point and the coordinate of the second point;
calculating an equation of the second straight line, based on the coordinate of the third point and the coordinate of the fourth point; and
calculating a coordinate corresponding to an intersection point between the imaginary first straight line and the second straight line, based on the equation of the imaginary first straight line and the equation of the second straight line,
wherein the coordinate of the intersection point corresponds to the coordinate of the actual point.

18. The method of claim 17, wherein the inspection key comprises:
a first inspection key;
a second inspection key disposed adjacent to the first inspection key in a first direction; and
a third inspection key disposed adjacent to the first inspection key in a second direction intersecting the first direction.

19. The method of claim 18, wherein the calculating the respective coordinates of the first point and the second point on the imaginary first straight line comprises:
calculating the coordinate of the first point based on a coordinate of the first inspection key and a distance between the first inspection key and the first point; and
calculating the coordinate of the second point based on a coordinate of the second inspection key and a distance between the second inspection key and the second point.

20. The method of claim 18, wherein the calculating the respective coordinates of the third point and the fourth point on the second straight line comprises:
calculating the coordinate of the third point based on a coordinate of the first inspection key and a distance between the first inspection key and the third point; and
calculating the coordinate of the fourth point based on a coordinate of the third inspection key and a distance between the third inspection key and the fourth point.

21. The method of claim 7, wherein the correcting the actual processing line further comprises:
correcting an entirety of the actual processing line in a shift manner.

22. The method of claim 21, wherein the detecting the coordinate of the actual point of the actual processing line and the moving the coordinate of the actual point to the coordinate of the target point of the preset target processing line corresponding to the actual point are performed after the correcting the entirety of the actual processing line in the shift manner.

23. The method of claim 7, wherein the correcting the actual processing line further comprises:
correcting an entirety of the actual processing line in a rotational manner.

24. The method of claim 23, wherein the detecting the coordinate of the actual point of the actual processing line and the moving the coordinate of the actual point to the coordinate of the target point of the preset target processing line corresponding to the actual point are performed after the correcting the entirety of the actual processing line in the rotational manner.

25. The method of claim 7, wherein the correcting the actual processing line further comprises:
correcting an entirety of the actual processing line in a scaling manner.

26. The method of claim 25, wherein the detecting the coordinate of the actual point of the actual processing line and the moving the coordinate of the actual point to the coordinate of the target point of the preset target processing line corresponding to the actual point are performed after the correcting the entirety of the actual processing line in the scaling manner.
